(19) United States
(12) Patent Application Publication
(10) Pub. No.: US 2017/0140977 A1
(43) Pub. Date: May 18, 2017

(54) CHUCK PIN, METHOD FOR MANUFACTURING A CHUCK PIN, APPARATUS FOR TREATING A SUBSTRATE

(71) Applicants: SEMES CO., LTD., Chungcheongnam-do (KR); INDUSTRY ACADEMY COOPERATION FOUNDATION OF SEJONG UNIVERSITY, Seoul (KR)

(72) Inventors: Chong-Min Ryu, Chungcheongbuk-do (KR); Won-Jun Lee, Seoul (KR); Seung-Ho Seo, Gyeonggi-do (KR)

(21) Appl. No.: 15/353,454

(22) Filed: Nov. 16, 2016

(30) Foreign Application Priority Data
Nov. 17, 2015 (KR) 10-2015-0161252
Jan. 8, 2016 (KR) 10-2016-0002728

(51) Int. Cl. H01L 21/687; C23C 16/32; B08B 3/08; B08B 3/02; B08B 3/10; C23C 16/458; H01L 21/67

(52) U.S. Cl. CPC H01L 21/68742; C23C 16/458; C23C 16/325; H01L 21/68757; H01L 21/67051; B08B 3/02; B08B 3/10; B08B 3/08

(57) ABSTRACT

A chuck pin, method for manufacturing a chuck pin, and an apparatus for treating substrate. The substrate treating apparatus includes a container having a treating space in its inner side, a supporting unit supporting the substrate inside of the treating space, and a liquid supply unit providing a solution to the supported substrate of the supporting unit. The supporting unit is placed in a supporting plate where the substrate is placed and in the above supporting plate, and includes a chuck pin supporting a side part of the substrate. The chuck pin is formed on a body and on the above surface of the body, and includes a first coating film provided as a silicon carbide material.

### CROSS-REFERENCE TO RELATED APPLICATIONS

A claim for priority under 35 U.S.C. §119 is made to Korean Patent Application No. 10-2015-0161252 filed on Nov. 17, 2015, and Korean Patent Application No. 10-2016-0002728 filed on Jan. 8, 2016 in the Korean Intellectual Property Office, the entire contents of which are hereby incorporated by reference herein.

### BACKGROUND

The present disclosure disclosed herein relates to a chuck pin for supporting a substrate, method for manufacturing a chuck pin, and an apparatus for treating a substrate.

Conventionally, in a method for manufacturing a flat panel display or a semiconductor device, a variety of processes such as photoresist coating process, a developing process, an etching process, and an ashing process are performed during treating a glass substrate or a wafer.

Particularly, as a semiconductor device becomes having high density, high integrity, and high performance, miniaturization of a circuit pattern rapidly happens and thereby, containments like a particle, an organic containment, a metal containment, etc. residing in a substrate surface highly influences a production yield and the device's characteristics. Therefore, a cleaning process removing different kinds of containments attached to the substrate surface is issued as an important process during a semiconductor manufacturing process, and cleaning the substrate is performed before and after each unit process of a semiconductor manufacturing process.

Meanwhile, the cleaning process uses treatment liquid such as a chemical, etc. But, frequently the chemical directly contact components of the substrate treating apparatus. As manufacturing processes are repeated, the components of the substrate treating apparatus get damaged by the chemical and need to be replaced periodically.

Particularly, a chuck pin which supports the substrate is directly contacted with the substrate and thus is directly contacted with the chemical during substrate treating process. Accordingly, the chuck pin has faster damaging rate by the chemical than the other components. When the chuck pin is damaged, it needs to be replaced and as the chuck pin gets damaged frequently, a replacement period gets rapid.

### SUMMARY

Embodiments of the present disclosure provide a chuck pin having good corrosion resistance and durability, method for manufacturing a chuck pin, and an apparatus for treating a substrate.

Also, embodiments of the present disclosure provide a chuck pin that could minimize occurrence factor of a particle occurring during substrate treating process by enhancing its corrosion resistance and durability, method for manufacturing a chuck pin, and an apparatus for treating a substrate.

Embodiments of present disclosure are not limited to hereinafter, and other objects thereof will be understandable by those skilled in the art from the following descriptions.

Embodiments of the present disclosure provide a substrate treating apparatus.

According to an embodiment of the present disclosure, the substrate treating apparatus comprises a container having a treating space therein; a supporting unit supporting a substrate in the treating space; and a liquid supply unit providing a solution to the substrate supported by the supporting unit, wherein the supporting unit comprises a supporting plate on which the substrate is placed and a chuck pin provided at the supporting unit as to support a side of the substrate, and wherein the chuck pin comprises a body and a first coating film provided as a silicon carbide material on a surface of the body.

According to an embodiment, the first coating film is formed by chemical vapor deposition (CVD).

According to an embodiment, the solution is a hydrofluoric acid, a sulfuric acid, a phosphoric acid, or a mixture thereof.

According to an embodiment, the chuck pin further comprises a second coating film formed on a surface of the first coating film, and wherein the second coating film is provided as a fluoride coating film.

According to an embodiment of the present disclosure, a chuck pin supporting a side of a substrate comprises: a body; and a first coating film provided as a silicon carbide material on a surface of the body.

According to an embodiment, the first coating film is formed by a chemical vapor deposition (CVD).

According to an embodiment, the chuck pin further comprises a second coating film on a surface of the first coating film, and wherein the second coating film is provided as a fluoride coating film.

According to an embodiment of the present disclosure, a method for manufacturing a chuck pin supporting a side of a substrate comprises: forming a first coating film provided as a silicon carbide material on a surface of the body, wherein the first coating film is formed by a chemical vapor deposition (CVD).

According to an embodiment, the method further comprises forming a second coating film provided as a fluoride coating film on a surface of the first coating film.

According to an embodiment, the fluoride coating film is formed by forming a covalent bond between the fluoride and the surface of the first coating film.

According to an embodiment, the method further comprises forming a defect on the surface of the first coating film before forming the fluoride coating film.

According to an embodiment, the defect is formed by treating the surface of the first coating film with an acid or alkaline solution, and wherein the fluoride coating film is formed by supplying a fluoride with the surface of the first coating film after the treating.

Objects of the inventive concept are not limited to the above mentioned effects. Other objects thereof will be understandable by those skilled in the art from the following descriptions and the present application.

### BRIEF DESCRIPTION OF THE DRAWINGS

FIG. 1 is a plan view of a substrate treating apparatus in accordance with an embodiment of the present disclosure.

FIG. 2 is a cross sectional view of a substrate treating apparatus provided in a process chamber of the FIG. 1 in accordance with an embodiment of the present disclosure.

FIG. 3 is a front view of a chuck pin of the FIG. 2.

FIG. 4 is a cross sectional view of the chuck pin of the FIG. 3 viewed from an A-A direction.

FIG. 5 is a front view of another embodiment of the chucking of the FIG. 3.

FIG. 6 is a cross sectional view of the chuck pin of the FIG. 5 viewed from a B-B direction.

FIG. 7 schematically shows a formation of a fluoride coating film on the chuck pin of the FIG. 5.

FIG. 8 schematically shows a fluoride bonding to a surface in the fluoride coating film of the FIG. 7.

### DETAILED DESCRIPTION

Various example embodiments will be described more fully hereinafter with reference to the accompanying drawings, in which some example embodiments are shown. The present disclosure may, however, be embodied in different forms and should not be construed as limited to the embodiments set forth herein. Rather, these embodiments are provided so that this disclosure will be thorough and complete, and will fully convey the scope of the present disclosure to those skilled in the art. Therefore, features of the drawings are exaggerated to emphasize definite explanation.

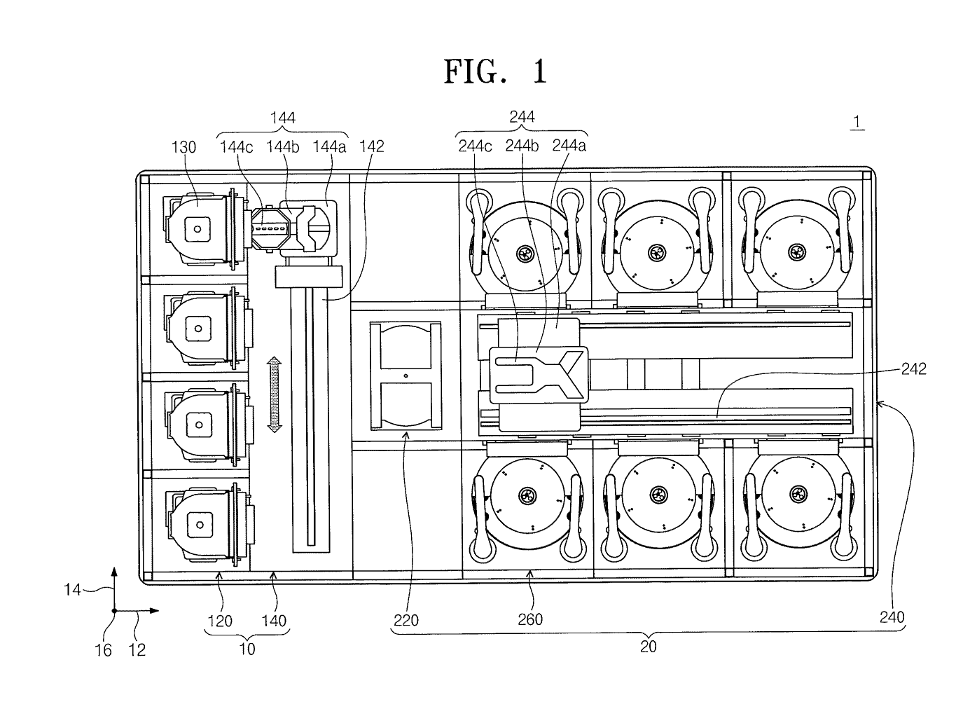

FIG. 1 is a plan view of a substrate treating apparatus in accordance with an embodiment of the present disclosure. Referring to the FIG. 1, a substrate treating apparatus 1 comprises an index module 10 and a process treating module 20. The index module 10 have a load port 120 and a transfer frame 140. The load port 120, the transfer frame 140, and the process treating module 20 are sequentially arranged in a row. Hereinafter, a direction where the load port 120, the transfer frame 140, and the process treating module are arranged is referred to as a first direction 12. And a direction perpendicular to the first direction 12 is referred to as a second direction 14, when view from a top side, and a direction perpendicular to a plane including the first direction 12 and the second direction 14 is referred to as a third direction 16.

A carrier 130 where a substrate W is stored is seated on the load port 120. The load port 120 is provided as a plurality of numbers and they are arranged in a row along the second direction 14. In the FIG. 1, it described that four load ports 120 are provided. However, the number of load ports 120 may be increased or decreased depending on a requirement like process efficiency and a footprint of the process treating module 20. In the carrier 130, a plurality of slots (not described) are provided to support an edge of the substrate W. A plurality of slots are provided along the third direction 16 and a plurality of substrates W is placed inside the carrier vertically stacked to each other along the third direction 16. A front opening unified pod (FOUP) may be used as the carrier 130.

The process treating module 20 comprises a buffer unit 220, a transfer chamber 240, and a process chamber 260. The transfer chamber 240 is provided such that the lengthwise direction thereof is parallel with the first direction 12. The process chambers 260 are provided in one side and the other side of the transfer chamber 240 along the second direction 14, respectively. The process chambers 250 are provided symmetrically in one and the other sides of the transfer chamber 240. Some of the process chambers 260 are placed along the lengthwise direction of the transfer chamber 240. Also, some of the process chambers 260 are placed vertically stacked to each other. That is, in one side of the transfer chamber 240, the process chambers 260 may be arranged in A×B (A and B are natural number of 1 or above) array. Herein, A is the number of the process chambers 250 which are provided along the first direction 12, and B is the number of process chambers 260 which are provided along the third direction 16. When four or six process chambers 260 are provided on one side of the transfer chamber 240, the process chambers 260 may be arranged in 2×2 or 3×2 arrays. The number of the process chamber 260 may be increased or decreased. Unlike described above, the process chamber 260 may be provided only on one side of the transfer chamber 240. Also, unlike described above, the process chamber 260 may be provided as a single layer at both sides of the transfer chamber 240.

The buffer unit 220 is arranged between the transfer frame 140 and the transfer chamber 240. The buffer unit provides a space for the substrate W to stay temporarily before transferring the substrate W between the transfer chamber 240 and the transfer frame 140. The slot (not described) where the substrate places is provided inside (e.g., inner wall) of the buffer unit 220, and the slots (not described) are provided with a plurality of numbers spaced apart from each other along the third direction 16. One side of the buffer unit 220 facing the transfer frame 140, and the other side of the buffer unit 220 facing the transfer frame 140 are opened.

The transfer frame 140 transfers the substrate W between the buffer unit 220 and the carrier 130 seated on the load port 120. In the transfer frame 140, an index rail 142 and an index robot 144 are provided. The index rail 142 is provided such that the lengthwise direction is parallel to the second direction 14. The index robot 144 is installed on the index rail 142, and move linearly along the index rail 142 to the second direction 14. The index robot 144 comprises a base 144a, a body 144b, and an index arm 144c. The base 133a is installed movably along the index rail 142. The body 144b is coupled to the base 144a. The body 144b is provided movably along the third direction 16 on the base 144a. Also, the body 144b is provided rotatable on the base 144a. The index arm 144c is coupled to the body 144b, and is provided to move front and back to the body 144b. The index arm 144c is provided with a plurality of numbers and they are driven independently. The index arms 144c are arranged vertically, i.e., spaced apart from each other along the third direction 16. Some of the index arms 144c may be used when transferring the substrate W from the process treating module 20 to the carrier 130, and some may be used when transferring the substrate W from the carrier 130 to the process treating module 130. In this way, during the index robot 144 carries in or carries out the substrate W, particles that have come from a substrate before treating process may be prevented from adhering to a substrate after treating process.

The transfer chamber 240 transfers the substrate W between process chambers 260 and the buffer unit 220 and between the process chambers 260. A guide rail 242 and a main robot 244 are provided in the transfer chamber 240. The guide rail 242 is places such that the lengthwise direction is parallel with the first direction 12. The main robot 244 is installed on the guide rail 242, and moves linearly along the first direction 12 on the guide rail 242. The main robot 244 comprises a base 244a, a body 244b, and a main arm 244c. The base 244a is installed movably along the guide rail 242. The body 244b is coupled to the base 244a. The body 244b is provided movably along the third direction 16 on the base 244a. Also, the body 244b is provided rotatable on the base 244a. The main arm 244c is coupled to the body 244b, and is provided to move front and back to the body 244b. The main arm 244c is provided with a plurality of numbers and they are provided to drive separately. The main arms 244c are arranged vertically, i.e., spaced apart from each other along the third direction 16. The main arm 244c used when transferring the substrate W from the buffer unit 220 to the process chamber 260, and the main arm 244c used when transferring the substrate W from the process chamber 260 to the buffer unit 220 may be different.

In the process chamber 260, a substrate treating apparatus 300 which performs a cleaning process to the substrate W is provided. The substrate treating apparatus 300 provided in each process chambers 240 may have different structure based on kinds of cleaning process. The substrate treating apparatus 300 provided in each process chambers 240 may have the same structure. In one embodiment, the process chambers 260 may be divided into a plurality of groups, and the substrate treating apparatus 300 provided in the same group of the process chamber 260 may have the same structure, and the substrate treating apparatus 300 provided in different group of the process chamber 260 may have different structure. For example, when the process chamber 260 is divided into two groups, a first group of the process chambers 260 are provided in one side of the transfer chamber 240, and a second group of the process chambers 260 are provided in the other side of the transfer chamber 240. In one embodiment, a first group of the process chamber 260 and a second group of the process chambers 260 are stacked in this order both in one side and the other side of the transfer chamber 240. The process chambers 260 may be divided into several groups depending on a kinds of chemicals or kinds of cleaning process used.

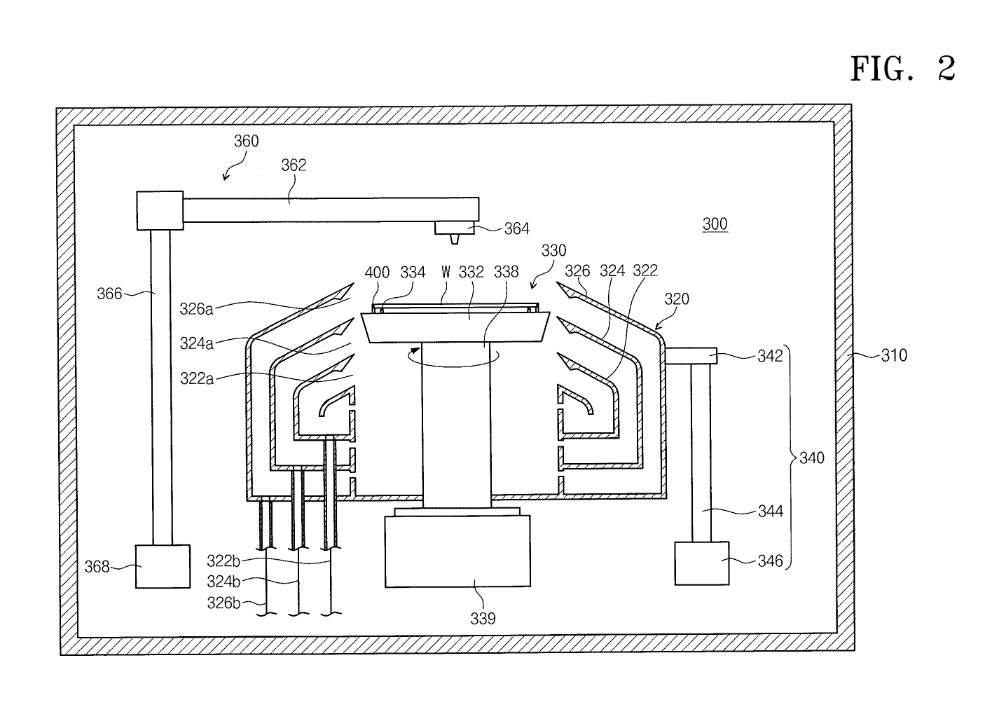

Hereinafter, as an example, a substrate treating apparatus 300 which cleans the substrate W using a treatment liquid will be described. FIG. 2 is a plan view of the substrate treating apparatus in accordance with an embodiment of the present application. Referring to FIG. 2, the substrate treating apparatus 300 comprises a housing 310, a container 320, a supporting unit 330, an elevator unit 340, a liquid supply unit 350, and a dissolved gas removal unit 400.

The housing 310 provides a space in its inner side. The container 320 is placed inside of the housing 310.

The container 320 provides a treating space where a substrate treating process is performed. The container 320 has open upper side. The container comprises an inner collecting container 322, a middle collecting container 324, and an outer collecting container 326. Each collecting containers 322, 324, 326 collects a treatment liquid that are different from each other among treatment liquids used in a process. The inner collecting container 322 is provided as a ring shape surrounding the supporting unit 330. The middle collecting container 324 is provided as a ring shape surrounding the inner collecting container 322. The outer collecting container 326 is provided as a ring shape surrounding the middle collecting container 324. An inner space 322a of the inner collecting container 322, an interspace 324a between the inner collecting container 322 and the middle collecting container 324, and an interspace 326a between the middle collecting container 324 and the outer collecting container 326 may function as a inlet where treatment liquid flows into the inner collecting container 322, the middle collecting container 324, and the outer collecting container 326, respectively. In the collecting containers 322, 324, 326, collecting lines 322b, 324b, 326b are connected which are extended vertically downward to the bottom, respectively. Collecting lines 322b, 324b, 326b emit the treatment liquid inflow through the collecting containers 322, 324, 326, respectively. The emitted treatment liquid may be reused through a treatment liquid regeneration system (not described) of outside.

The supporting unit 330 is placed inside of the container 320. The supporting unit 330 supports the substrate W and rotates the substrate W during the substrate treating process. The supporting unit 330 comprises a supporting plate 332, a supporting pin 334, a chuck pin 400, and a supporting shaft 338. The supporting plate 332 has an upper surface usually provided as a circular form, when viewed from a top side. At the bottom of the supporting plate 332 the supporting shaft 338 rotatable by a motor 339 is fixedly connected. The supporting pin 334 is provided with a plurality of numbers. The plurality of supporting pins 334 are spaced apart from each other on edge of the upper surface of the supporting plate 332 and protrude upward from the supporting plate 332. The supporting pins 334 are generally arranged to have a ring shape. The supporting pin 334 supports the back side of the substrate W as to be spaced apart from the upper surface of the supporting plate 332.

The chuck pin 400 is provided as a plurality number. The chuck pin 400 is arranged further apart from a center of the supporting plate 332 than the supporting pin 334. The chuck pin 400 is provided as to protrude upward from the supporting plate 332. The chuck pin 400 supports lateral part (side) of the substrate W such that the substrate W does not deviate from a right position to a side direction when the supporting unit 330 is rotating. The chuck pin 400 is provided to move linearly between standby position and supporting position along a radius direction of the supporting plate 332. The standby position is further apart from a center of the supporting plate 332 than the supporting position. When loading and unloading the substrate W on and from the supporting unit 330, and when processing the substrate W, the chuck pin 400 is placed on the supporting position. The chuck pin 400 on the supporting position is contacted with the lateral part of the substrate.

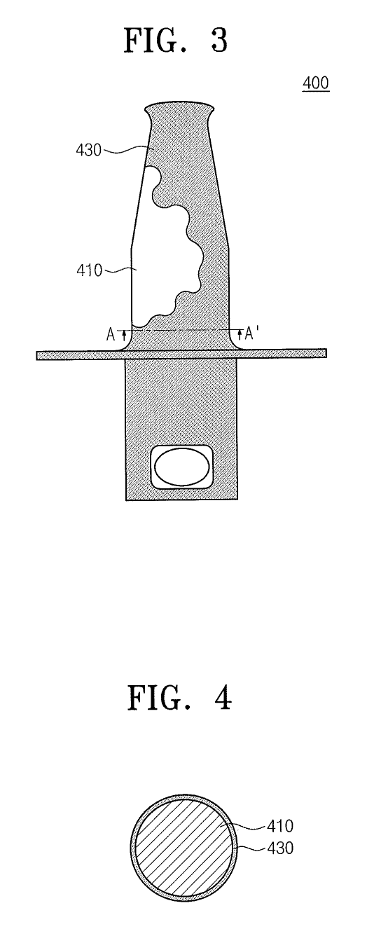

FIG. 3 is a front view of a chuck pin of the FIG. 2. FIG. 4 is a cross sectional view of the chuck pin of the FIG. 3 taken along A-A line. Hereinafter, referring to FIGS. 3 and 4, the chuck pin 400 comprises a body 410 and a first coating film 430.

The first coating film 430 is formed on a surface of the body 410. The first coating film 430 is provided to surround a surface of the chuck pin 400. When the chuck pin 400 is provided as plurality numbers, the first coating film 430 may be provided to a plurality of chuck pins 400. In an example, the first coating film 430 may be provided as a silicon carbide (SiC) material. The first coating film 430 may be formed by a chemical vapor deposition (CVD).

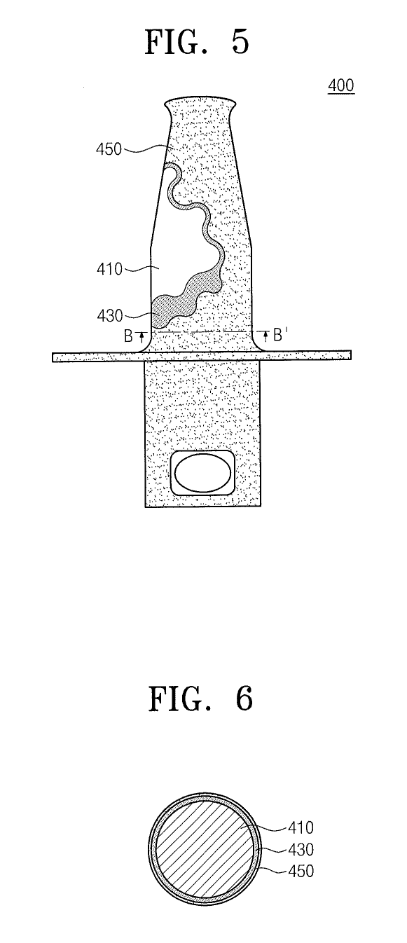

FIG. 5 is a front view of another embodiment of the chucking of the FIG. 3. FIG. 6 is a cross sectional view of the chuck pin of the FIG. 5 taken along B-B line. Hereinafter, referring to FIGS. 5 and 6, a chuck pin 400 comprises a body 410, a first coating film 430, and a second coating film 450.

The first coating film 430 is formed on a surface of the body 410. The first coating film 430 is provided to surround a surface of the chuck pin 400. In an example, the first coating film 430 may be provided as a silicon carbide (SiC) material. The first coating film 430 may be formed by a chemical vapor deposition (CVD).

The second coating film 450 is formed on a surface of the first coating film 430. The second coating film 450 is provided to surround the surface of the first coating film 430. In an example, the second coating film 450 may be provided as a fluoride coating film. In an example, the fluoride coating film may be formed by fluorine covalently bonding to the surface of the first coating film 430. Hereinafter, it will be described that a fluoride coating film is provided as the second coating film 450.

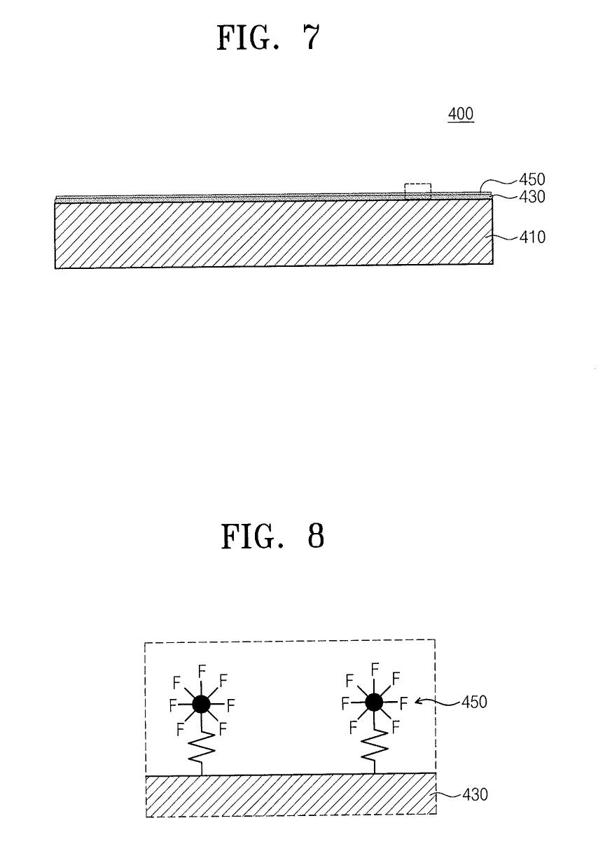

FIG. 7 schematically shows a formation of a fluoride coating film on the chuck pin of the FIG. 5. FIG. 8 schematically shows a fluoride bonding to a surface in the fluoride coating film of the FIG. 7. Hereinafter, referring to FIGS. 7 and 8, a method for forming the fluoride coating film comprises performing a chemical treatment on the surface of the first coating film 430. The first coating film 430 which is made of silicon carbide material is chemically stable. Thus, it may be required to perform the chemical treatment on the surface of the first coating film 430. When providing a fluoride without the chemical treatment on the surface of the first coating film 430, the fluoride coating film may not be formed.

The chemical treatment on the surface forms a defect on a surface of the silicon carbide. In an example, the chemical treatment on the surface forms a defect on the surface comprises treating the surface with acid or alkaline solution. After treating the surface, fluoride is provided and a fluoride coating film is formed on the surface via fluoride covalent bond. The fluoride is bonded to the surface of the first coating film through covalent bond.

Again, referring to FIG. 2, the elevator unit 340 moves the container 320 linearly to up and down direction. As the container 320 moves up and down, a height of the container 320 relative to the supporting unit 330 is changed. The elevator unit 320 comprises a bracket 342, a moving shaft 344, and a driver 346.

The bracket 342 is fixedly installed on outer wall of the container 320. The moving shaft 344 moving up and down direction by the driver 346 is fixedly coupled to the bracket 342. When the substrate W is placed on the supporting unit 330 or when lifted from the supporting unit 330, the container 320 descends such that the supporting unit 330 protrudes upward from the container 320. Also, during processing, the height of the container 320 are controlled such that the treatment liquid flows into the predetermined collecting containers 322, 324, 326 depending on a kind of treatment liquid supplied in substrate W.

In an example, during treating the substrate W with the first treatment liquid, the substrate W is placed on a height corresponding to the inner space 322a of the inner collecting container 322. Also, when treating the substrate W with the second treatment liquid and the third treatment liquid, the substrate W is placed on a height corresponding to the interspace 324a between the inner collecting container 322 and the middle collecting container 324, and the interspace 326a between the middle collecting container 324 and the outer collecting container 326, respectively. Unlike described above, the elevator unit 340 may move the supporting unit 330 up and down direction instead of the container 320.

A liquid supply unit 360 supplies a treatment liquid to the substrate W when processing the substrate W treatment.

The liquid supply unit 360 comprises a nozzle support 362, a nozzle 364, a supporting shaft 366, and a driver 368.

The supporting shaft 366 is provided such that its lengthwise direction is parallel with the third direction 16, and the driver 368 is coupled to the bottom of the supporting shaft 366. The driver 368 rotates and elevates the supporting shaft 366 up and down. The nozzle support 362 is perpendicularly coupled to the supporting shaft 366 at one end that is opposite to the other end to which driver 368 is coupled. The nozzle 364 is installed on bottom the nozzle support 362 at one end that is opposite to the other end to which the supporting shaft 366 is coupled. The nozzle 364 is moved to a processing position and a standby position by the driver 364. The processing position is where the nozzle 364 is located vertically above the container 320, and the standby position is where the nozzle 364 is out of the vertically above the container 320. The nozzle 364 supplies a liquid to the substrate W by supplying a liquid from outside.

The liquid supply unit 320 may be provided with one or plurality numbers. When the liquid supply unit 320 is provided with plurality numbers, a chemical, a rinse liquid, or an organic solvent may be provided through different liquid supply unit 360. When the liquid is provided as a chemical liquid, the chemical may be a hydrofluoric acid, a sulfuric acid, a phosphoric acid, or a mixture thereof. The rinse liquid may be deionized water, and the organic solvent may be a mixed solution of inert gas and isopropyl alcohol gas or an isopropyl alcohol liquid.

In the embodiment of the present disclosure described above, the first coating film 340 is provided on the surface of the body 410 of the chuck pin 400. The first coating film 430 forms a coating film on the surface of the body 410 using CVD. The present disclosure may enhance corrosion resistance of the chuck pin 400 using the CVD to the first coating film 430.

According to a test result, the corrosion resistance of the first coating film 430 formed by a reaction sintering process is lower than the corrosion resistance of the first coating film 430 formed by CVD. Also, when forming the first coating film 430 by pressure-less sintering process, the corrosion resistance is good, but a manufacturing cost is expensive and an electrification of the chuck pin 400 is low. Herein, electrification of the chuck pin 400 may increase efficiency of the substrate treating process by emitting an electric charge, etc. occurring during the substrate treating process outside by grounding the chuck pin 400. However, the experiment result shows that when forming the first coating film 430 by pressure-less sintering process, electrification of the chuck pin 400 is lower than when forming the first coating film 430 by CVD.

That is, when forming the first coating film 430 by CVD, the corrosion resistance, durability, and a chemical resistance are better than by the reaction sintering process, and the electrification was better than by the pressure-less sintering process. When forming the first coating film 430 by CVD, it satisfies an electrical property of below 10⁵Ω. The electrical property of the first coating film 430 may enhance an antistatic effect.

Therefore, the surface of the chuck pin 400 of the present disclosure may enhance the corrosion resistance, durability, and the chemical resistance of the chuck pin 400 by providing the first coating film 430 using CVD. Also, enhancement of the corrosion resistance enhances the durability and thereby the replacement period prolongs.

Also, according to an another embodiment of the present disclosure, the corrosion resistance of the chuck pin 400 may further enhanced by providing the second coating film 450 provided as the fluoride coating film like the first coating film 430, and a durability may be enhanced too.

Also, the present disclosure forms the first coating film 430 or the second coating film 450 on the surface of the chuck pin 400 and thereby enhance an efficiency of the substrate treating process by minimizing occurrence of the particle that may occur from the chuck pin 400 using a liquid used during the substrate treating process.

In the embodiments described above, as an example, the chuck pin was coated with the first and second coating films but the object to be coated is not limited to the chuck pin. In an example, the coating film may be formed on any components that needs enhancement of the corrosion resistance, durability, and the chemical resistance.

Further, the material of the chuck pin, the first and second coating films is not limited to the embodiments described above. In an example, the film may be a silicon carbide material film, or a combination of silicon carbide material and a fluoride film. Herein the silicon carbide material film may be formed by CVD. Also, the silicon carbide material film and the fluoride material film may covalently bond.

Foregoing embodiments are examples of the present disclosure. Further, the above contents merely illustrate and describe preferred embodiments and embodiments may include various combinations, changes, and environments. That is, it will be appreciated by those skilled in the art that substitutions, modifications and changes may be made in these embodiments without departing from the principles and spirit, the scope of which is defined in the appended claims and their equivalents. Further, it is not intended that the scope of this application be limited to these specific embodiments or to their specific features or benefits. Rather, it is intended that the scope of this application be limited solely to the claims which now follow and to their equivalents.

What is claimed is:

1. A substrate treating apparatus comprising:
a container having a treating space therein;
a supporting unit supporting a substrate in the treating space; and
a liquid supply unit providing a solution to the substrate supported by the supporting unit;
wherein the supporting unit comprises a supporting plate on which the substrate is placed and a chuck pin provided at the supporting unit as to support a side of the substrate, and
wherein the chuck pin comprises a body and a first coating film provided as a silicon carbide material on a surface of the body.

2. The apparatus of claim 1, wherein the first coating film is formed by chemical vapor deposition (CVD).

3. The apparatus of claim 1, wherein the solution is a hydrofluoric acid, a sulfuric acid, a phosphoric acid, or a mixture thereof.

4. The apparatus of claim 1, wherein the chuck pin further comprises a second coating film formed on a surface of the first coating film, and wherein the second coating film is provided as a fluoride coating film.

5. A chuck pin supporting a side of a substrate comprising;
a body; and
a first coating film provided as a silicon carbide material on a surface of the body.

6. The chuck pin of claim 5, wherein the first coating film is formed by a chemical vapor deposition (CVD).

7. The chuck pin of claim 5, wherein the chuck pin further comprises a second coating film on a surface of the first coating film, and wherein the second coating film is provided as a fluoride coating film.

8. A method for manufacturing a chuck pin supporting a side of a substrate comprising:
forming a first coating film provided as a silicon carbide material on a surface of a body;
wherein the first coating film is formed by a chemical vapor deposition (CVD).

9. The method of claim 8, further comprising forming a second coating film provided as a fluoride coating film on a surface of the first coating film.

10. The method of claim 9, wherein the fluoride coating film is formed by forming a covalent bond between the fluoride and the surface of the first coating film.

11. The method of claim 10, further comprising forming a defect on the surface of the first coating film before forming the fluoride coating film.

12. The method of claim 11, wherein the defect is formed by treating the surface of the first coating film with an acid or alkaline solution, and wherein the fluoride coating film is formed by supplying a fluoride with the surface of the first coating film after the treating.
